(19) United States
(12) Patent Application Publication
(10) Pub. No.: US 2016/0135320 A1
(43) Pub. Date: May 12, 2016

(54) CIRCUIT ASSEMBLY WITH VIBRATION-PROOF CIRCUIT COMPONENT FIXING STRUCTURE, AND VEHICULAR ELECTRIC COMPRESSOR

(71) Applicant: MITSUBISHI HEAVY INDUSTRIES AUTOMOTIVE THERMAL SYSTEMS CO., LTD., Aichi (JP)

(72) Inventors: Shunsuke YAKUSHIJI, Tokyo (JP); Takuma YAMASHITA, Tokyo (JP); Takayuki TAKASHIGE, Kiyosu-shi (JP)

(73) Assignee: MITSUBISHI HEAVY INDUSTRIES AUTOMOTIVE THERMAL SYSTEMS CO., LTD., Kiyosu-shi, Aichi (JP)

(21) Appl. No.: 14/903,264

(22) PCT Filed: Sep. 25, 2014
(86) PCT No.: PCT/JP2014/004915

§ 371 Date: Jan. 6, 2016

(30) Foreign Application Priority Data
Sep. 27, 2013 (JP) 2013-201793

(51) Int. Cl. H05K 7/14; F04C 29/00; F04C 28/08; F04C 18/02

(52) U.S. Cl. CPC H05K 7/1417; F04C 18/0215; F04C 29/0085; F04C 28/08; H05K 7/1427

(57) ABSTRACT

Provided are a circuit assembly including a circuit component fixing structure capable of preventing damage to a fixing portion and a connection terminal caused by vibrations, and a vehicular electric compressor. The circuit assembly includes: a circuit board; a circuit component connected to the circuit board; and a circuit casing housing both the circuit board and the circuit component. The circuit component includes a component body disposed facing the circuit board inside the circuit casing, a connection terminal directly fixed to the circuit board, and a first fixing portion and a second fixing portion that are fixed to the circuit casing around the component body. In a direction orthogonal to the circuit board, the first fixing portion is positioned on a side of the circuit board with respect to the center of gravity of the circuit component, and the second fixing portion is positioned on a side away from the circuit board with respect to the center of gravity.

### TECHNICAL FIELD

The present invention relates to a circuit assembly provided with a vibration-proof fixing structure for a circuit component, such as a capacitor, and also to a vehicular electric compressor provided with the circuit assembly having the circuit component.

### BACKGROUND ART

An electric compressor configuring a vehicular air conditioner is provided with a circuit assembly functioning as a circuit for driving and controlling a motor. The circuit assembly includes a circuit board to which various circuit components are connected, and a circuit casing housing both the circuit components and the circuit board. The circuit casing is fixed to a housing of the electric compressor.

The circuit components include relatively small components, such as switching elements, and Integrated Circuit (IC) chips, and relatively large components, such as noise-cutting capacitors and coils.

A casing for housing the large circuit components is prepared separately from the circuit casing in which the circuit board is housed (Patent Literature 1).

In an electric compressor described in Patent Literature 1, a circuit casing is provided on a side surface, in a vertical direction, of a housing of the compressor, and a casing for housing a capacitor is provided on a side surface, in a horizontal direction, of the housing. A connection terminal of the capacitor is connected to an electrode extending from the circuit casing.

### CITATION LIST

### Patent Literature

Patent Literature 1: Japanese Unexamined Patent Application Publication No. 2004-19586A

### SUMMARY OF INVENTION

### Technical Problem

In particular, a circuit component provided in a vehicle operates under a severe vibration environment in which the circuit component is affected by engine vibrations, road surface vibrations, and the like.

Even though large circuit components, such as a capacitor, are fixed to a casing, when those components are excited by vibrations transmitted from the surroundings, large loads are applied to a fixing portion fixed to the casing, and a connection terminal.

In order to prevent damage caused as a result of this, it is not only necessary to improve a rigidity of the fixing portion and the connection terminal or increase the number of fixing locations, but a fundamental improvement of a structure for fixing the circuit component is also required.

An object of the present invention is to provide a circuit assembly that includes a circuit component fixing structure capable of preventing damage to a fixing portion and a connection terminal caused by vibrations, and a vehicular electric compressor.

### Solution to Problem

A first circuit assembly according to the present invention includes: a circuit board; a circuit component connected to the circuit board; and a casing housing both the circuit board and the circuit component.

The circuit component includes a component body disposed facing the circuit board inside the circuit casing, a connection terminal directly fixed to the circuit board, and a first fixing portion and a second fixing portion that are fixed to the circuit casing around the component body.

Then, in the present invention, the first fixing portion is positioned on a side of the circuit board with respect to the center of gravity of the circuit component in a direction orthogonal to the circuit board. The second fixing portion is positioned on a side away from the circuit board with respect to the center of gravity in the direction orthogonal to the circuit board.

According to the present invention, compared with a case in which the circuit component is fixed on one side of the center of gravity, an exciting force acting upon the center of gravity is received in a well-balanced manner from both sides of the center of gravity by the first fixing portion and the second fixing portion. As a result, it is possible to suppress a displacement or a deformation of the circuit component caused by vibrations. Thus, even under a severe vibration environment, it is possible to prevent damage to the first fixing portion, the second fixing portion, and the connection terminal.

In the first circuit assembly of the present invention, it is preferable that the first fixing portion be positioned on one side of a straight line drawn in an in-plane direction of the circuit board so as to pass through the center of gravity, and the second fixing portion be positioned on the other side of the straight line.

As a result, in the in-plane direction of the circuit board also, the exciting force acting upon the center of gravity is received in a well-balanced manner from both sides of the center of gravity by the first fixing portion and the second fixing portion. Thus, it is possible to more sufficiently prevent the damage to the first fixing portion, the second fixing portion, and the connection terminal.

A second circuit assembly of the present invention includes: a circuit board; a circuit component connected to the circuit board; and a casing housing both the circuit board and the circuit component.

The circuit component includes a component body disposed facing the circuit board inside the casing, a connection terminal directly fixed to the circuit board, and at least two fixing portions fixed to the casing around the component body.

Then, in the present invention, a center of gravity of the circuit component is positioned inside the shape obtained by linking the connection terminal and the fixing portions.

According to the present invention, the exciting force acting upon the center of gravity of the circuit component is received in a well-balanced manner by the fixing portions and the connection terminal that are disposed around the center of gravity.

The exciting force acting upon the center of gravity in the direction orthogonal to the circuit board, in the in-plane direction of the circuit board, and in any other direction is sufficiently and evenly borne in a non-biased manner by the fixing portions, and the connection terminal, which form vertices of the shape that has the center of gravity as its centroid.

Thus, it is possible to reliably prevent the damage to the fixing portions and the connection terminal.

In the second circuit assembly of the present invention, when one of a positive connection terminal and a negative connection terminal forming the connection terminal is directly fixed to the circuit board, the other can be used as one of the fixing portions.

An electric compressor of the present invention includes: the above-described circuit assembly; a motor driven by a circuit operation of the circuit assembly; and a compression mechanism compressing a fluid using a driving force transmitted by the motor. The electric compressor is mounted in a vehicle.

By including the above-described circuit assembly, it is possible to benefit from the same effects as those described above.

### Advantageous Effects of Invention

According to the present invention, it is possible to provide a circuit assembly that includes a circuit component fixing structure capable of preventing damage to a fixing portion and a connection terminal caused by vibrations, and a vehicular electric compressor.

### BRIEF DESCRIPTION OF DRAWINGS

FIG. 1 is a vertical cross-sectional view of an electric compressor according to a first embodiment of the present invention.

FIG. 2 is an exploded perspective view illustrating a circuit assembly of the electric compressor.

FIG. 3 is a plan view of the circuit assembly of the electric compressor. (A state in which a circuit board is removed)

FIG. 4A is a perspective view of a circuit component (a capacitor). FIG. 4B is a schematic view illustrating positions of fixing portions of the circuit component (the capacitor).

FIG. 5A is a view schematically illustrating a circuit component fixing structure according to a second embodiment. FIG. 5B is a view schematically illustrating the circuit component fixing structure according to a modified example of the second embodiment.

### DESCRIPTION OF EMBODIMENTS

Embodiments of the present invention will be described below with reference to the appended drawings.

### First Embodiment

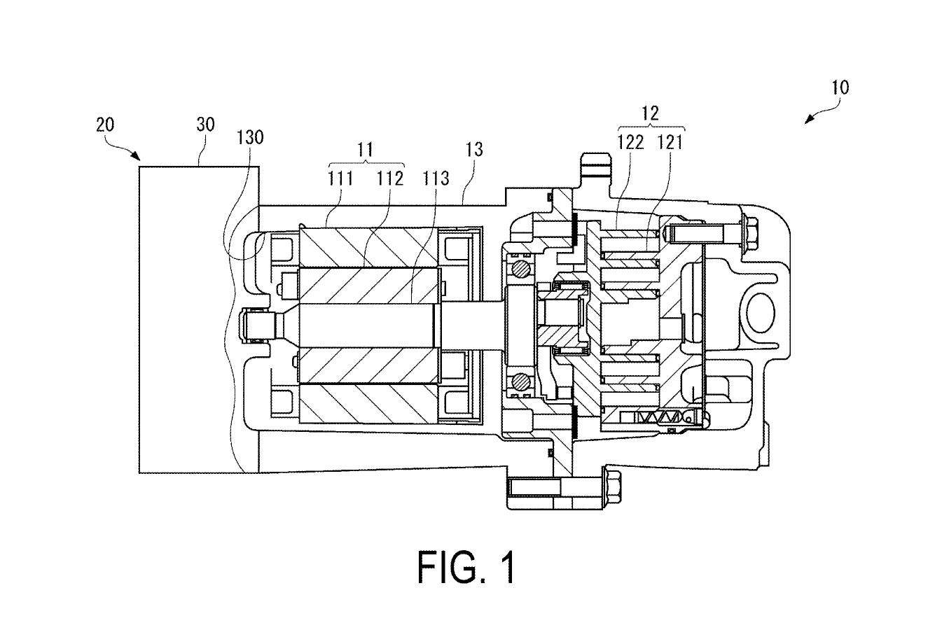

An electric compressor 10 illustrated in FIG. 1 is applied to an air conditioner mounted in a vehicle. The electric compressor 10 is provided with a motor 11, a compression mechanism 12, a housing 13 housing the motor 11 and the compression mechanism 12, and a circuit assembly 20 functioning as a circuit for driving and controlling the motor 11.

The motor 11 is provided with a stator 111 that is fixed to the housing 13, and a rotor 112 that is caused to rotate with respect to the stator 111. The rotor 112 is rotated by a three-phase alternating current supplied to the stator 111 by the circuit assembly 20.

The compression mechanism 12 is provided with a fixed scroll 121 that is fixed to the housing 13, and an orbiting scroll 122 that is set in a revolving orbiting motion with respect to the fixed scroll 121.

The orbiting scroll 122 is eccentrically coupled to a shaft 113 fixed to the rotor 112.

The housing 13 is formed in a cylindrical shape having an axis along the shaft 113. Inside the housing 13, the motor 11 is disposed on one end side and the compression mechanism 12 is disposed on the other end side.

The housing 13 is supported by a vehicle engine in an attitude in which the axis of the housing 13 is facing in a horizontal direction.

The housing 13 has an opening 130 on the one end side. The opening 130 is closed by a circuit casing 30 of the circuit assembly 20.

An interior of the housing 13 is sealed by a packing, which is not illustrated in the drawings, between a periphery of the opening 130 and the circuit casing 30.

The electric compressor 10 operates in the following manner.

An electric current is supplied by the circuit assembly 20 to the stator 111 of the motor 11, so as to drive the motor 11.

Furthermore, a refrigerant is introduced into the interior of the housing 13 from a refrigerant circuit that is not illustrated in the drawings.

When the orbiting scroll 122 is caused to turn as a result of the shaft 113 being rotated by a driving force of the motor 11, the refrigerant is sucked into a compression chamber between the fixed scroll 121 and the orbiting scroll 122. The compression mechanism 12 compresses the refrigerant as a result of a reduction in a capacity of the compression chamber caused by turning of the orbiting scroll 122. The compressed refrigerant is discharged to the refrigerant circuit located outside.

Next, a configuration of the circuit assembly 20 will be described.

The circuit assembly 20 is integrated with the housing 13.

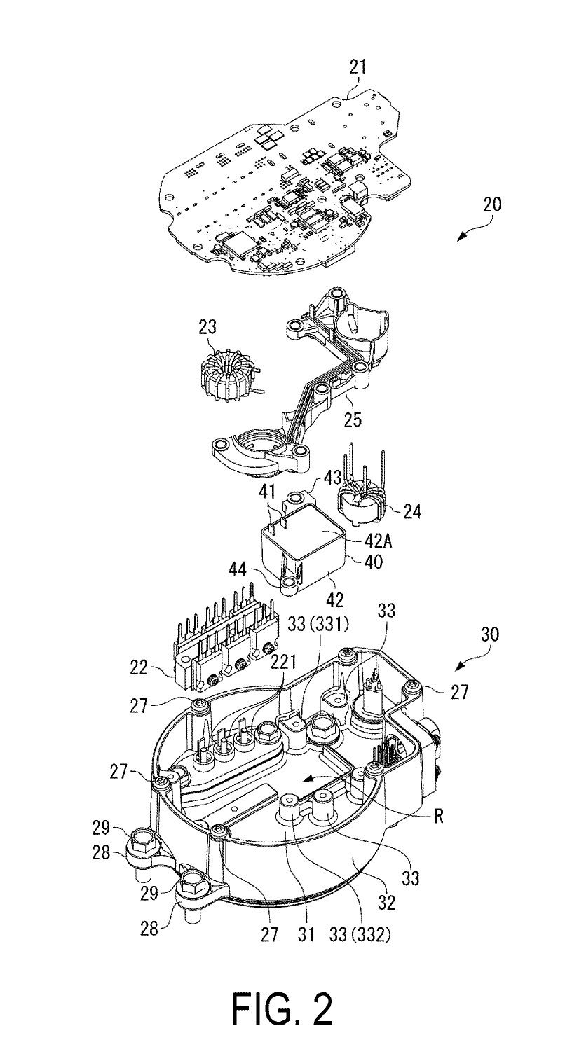

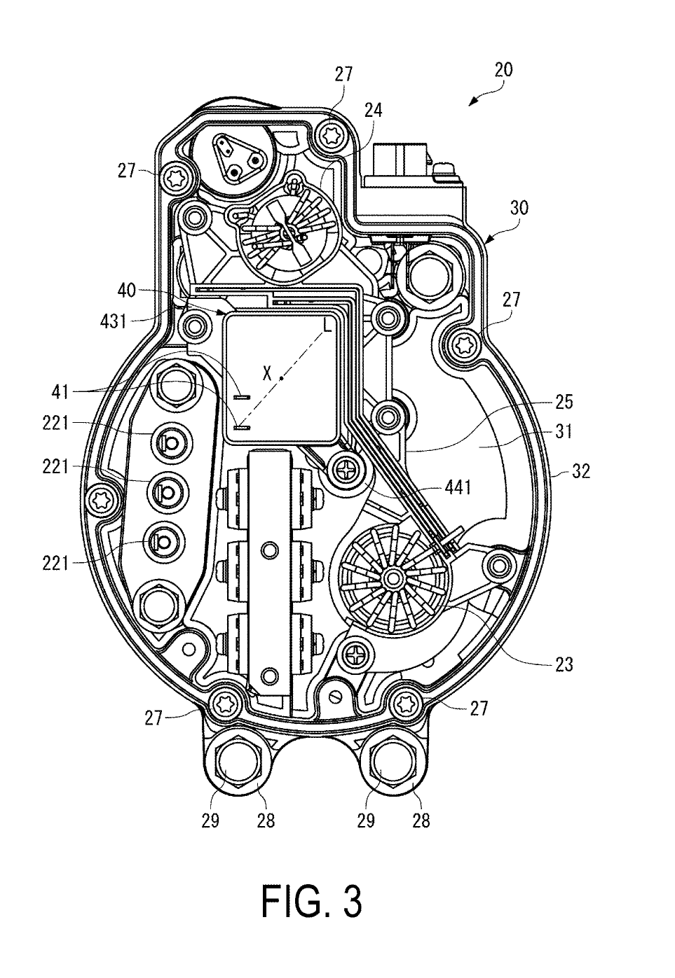

As illustrated in FIG. 2 and FIG. 3, the circuit assembly 20 is provided with a circuit board 21 on which various circuit elements are provided, a plurality of circuit components 22 to 25, and 40 connected to the circuit board 21, and the circuit casing 30 housing both the circuit board 21 and the circuit components 22 to 25, and 40.

Note that the circuit board 21 is removed in FIG. 3.

The circuit casing 30 is provided with a partition wall 31 partitioning an interior of the circuit casing 30 from the interior of the housing 13, a peripheral wall 32 standing from a periphery of the partition wall 31, and a lid that is attached to an upper edge of the peripheral wall 32 and that is not illustrated in the drawings.

The partition wall 31 closes the opening 130 of the housing 13. In the inside of the partition wall 31 (inside the circuit casing 30), a plurality of bosses 33 are provided that support the circuit board 21 and the circuit components 22 to 25, and 40.

The peripheral wall 32 surrounds the circuit board 21 and the circuit components 22 to 25, and 40. The lid is fixed to the upper edge of the peripheral wall 32 by a plurality of bolts 27. The packing is sandwiched between the upper edge of the peripheral wall 32 and the lid.

The circuit casing 30 is fixed to the housing 13 by a plurality of fixing portions 28, which are provided on an outer side of the peripheral wall 32, using bolts 29.

The circuit board 21 has circuit elements, such as a switching element for generating a driving signal supplied to the motor 11, and an IC chip for driving and controlling the motor 11. The circuit elements are disposed on both front and back surfaces of the circuit board 21. Electric power is supplied to the circuit board 21 from a battery that is not illustrated in the drawings.

The circuit board 21 is fixed by bolts to the bosses 33 protruding from the partition wall 31.

Sizes and masses of the circuit components 22 to 25, and 40 are large compared with the circuit elements provided on the circuit board 21. These circuit components 22 to 25, and 40 are disposed in a space between the circuit board 21 and the partition wall 31 so as to be housed therein in a well-fitting manner, and are fixed by bolts to the bosses 33 protruding from the partition wall 31.

The circuit component 22 is a switching element. This switching element is connected to a terminal portion of the circuit board 21.

The circuit components 23 and 24 are both coils, and the circuit component 40 is a capacitor. These coils and capacitor are used to eliminate noise from a driving signal.

The circuit component 40 (the capacitor) is directly fixed to the circuit board 21 by a connection terminal 41 facing the circuit board 21.

The circuit component 25 is an electrode used to mutually connect the circuit components 23, 24, and 40 and the circuit board 21. The circuit component 25 (the electrode) supports the circuit components 23 and 24 (the coils).

The present embodiment is characterized by a fixing structure for fixing the circuit component 40 (the capacitor) to the circuit casing 30.

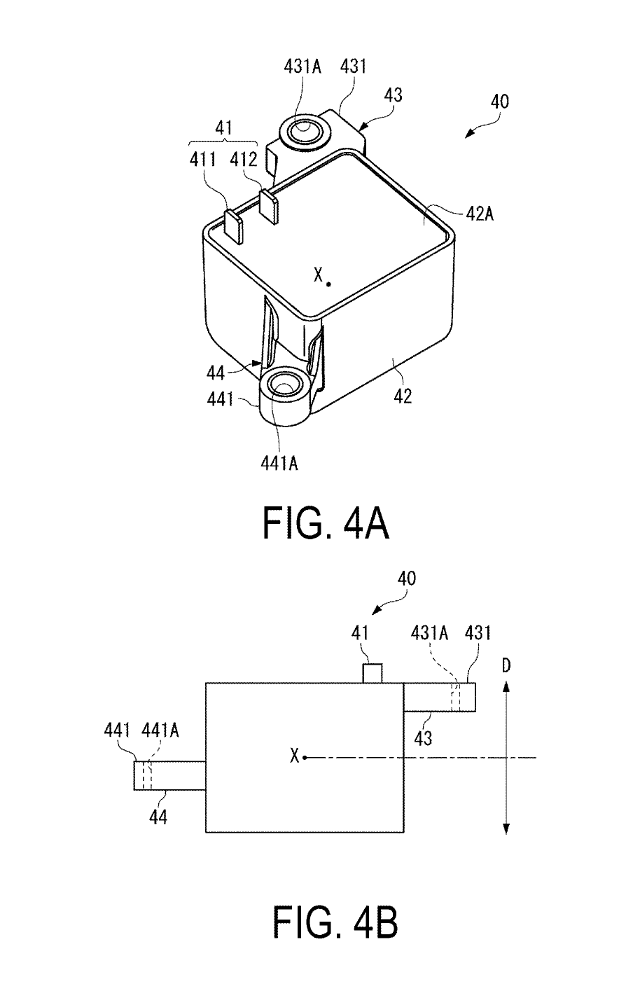

As illustrated in FIG. 2 and FIG. 4A, the circuit component 40 is provided with a component body 42, the connection terminal 41 fixed to the circuit board 21, and fixing arms 43 and 44 fixed to the circuit casing 30.

The component body 42 has a capacitor storing an electrical charge and a casing housing the capacitor. The component body 42 is formed in a substantially cuboid shape.

The component body 42 is disposed in a specific region R of the partition wall 31. A specific facing surface 42A of the component body 42 faces the circuit board 21.

The connection terminal 41 is formed by a positive connection terminal 411 and a negative connection terminal 412, each protruding from the facing surface 42A of the component body 42. The positive connection terminal 411 and the negative connection terminal 412 are directly fixed to the circuit board 21 as a result of being inserted into recesses of the terminal portion that is provided in the circuit board 21 and that is not illustrated in the drawings.

The fixing arms 43 and 44 are provided in the component body 42 so as to protrude further to the outer side than side surfaces of the component body 42 that are orthogonal to the facing surface 42A.

The fixing arm 43 has a fixing portion 431 (a first fixing portion) on a leading end side of the fixing arm 43.

The fixing arm 44 also has a fixing portion 441 (a second fixing portion) on a leading end side of the fixing arm 44. The fixing portions 431 and 441 are positioned around the component body 42.

A bolt hold 431A is formed in the fixing portion 431.

A bolt hold 441A is formed in the fixing portion 441.

The fixing portion 431 is fixed to a boss 331 (FIG. 2), which is one of the above-described bosses 33 of the partition wall 31, by a bolt inserted through the bolt hole 431A.

The fixing portion 441 is fixed to a boss 332 (FIG. 2), which is one of the above-described bosses 33 of the partition wall 31, by a bolt inserted through the bolt hole 441A.

The present embodiment is characterized by positions of the fixing portions 431 and 441, whereby a vibration resistance of the circuit component 40 is secured.

The positions of the fixing portions 431 and 441 are determined in accordance with a position of a center of gravity X of the circuit component 40 illustrated in FIGS. 4A and 4B.

As illustrated in FIG. 4B, the fixing portion 431 is positioned on a side of the circuit board 21 with respect to the center of gravity X, in a direction D that is orthogonal to the circuit board 21.

Meanwhile, the fixing portion 441 is positioned on a side away from the circuit board 21 with respect to the center of gravity X in the direction D that is orthogonal to the circuit board 21.

As described above, the positions of the fixing portions 431 and 441 are different in the direction D that is orthogonal to the circuit board 21. In addition, as illustrated in FIG. 3, planar positions of the fixing portions 431 and 441, in other words, the positions of the fixing portions 431 and 441 in an in-plane direction of the circuit board 21 are also different.

The fixing portion 431 is positioned on one side of a straight line L drawn in the in-plane direction of the circuit board 21 so as to pass through the center of gravity X. The fixing portion 441 is positioned on the other side of the straight line L.

Vibrations are transmitted to the circuit assembly 20 from vibration sources, such as an engine, the motor 11, the compression mechanism 12, an axle and a steering apparatus of the vehicle. Furthermore, vibrations are also transmitted from the road surface as a result of traveling of the vehicle. As a result, the circuit board 21 and the circuit components included in the circuit assembly 20 are excited.

At this time, when the circuit component 40, which has a large mass and is directly fixed to the circuit board 21, vibrates, large loads are applied to the connection terminal 41 and the fixing portions 431 and 441. Therefore, there is a strong need to prevent damage to the connection terminal 41 and the fixing portions 431 and 441.

Thus, in the present embodiment, the fixing portion 431 positioned on the side of the circuit board 21 with respect to the center of gravity X and the fixing portion 441 positioned on the side away from the circuit board 21 with respect to the center of gravity X are provided on the circuit component 40, as described above.

As a result, compared with a case in which the circuit component 40 is fixed on one side of the center of gravity X, an exciting force acting upon the center of gravity X is received in a well-balanced manner from both sides of the center of gravity X by the fixing portion 431 and the fixing portion 441.

The same applies to a surface direction. Because the fixing portions 431 and 441 are positioned on both sides of the straight line L passing through the center of gravity X in the in-plane direction of the circuit board 21, the exciting force acting upon the center of gravity X is received in a well-balanced manner from both sides of the center of gravity X by the fixing portion 431 and the fixing portion 441.

Thus, displacement and deformation of the circuit component 40 because of the vibrations can be suppressed. As a result of the circuit component 40 being fixed to the circuit casing 30 by the fixing portions 431 and 441 positioned on the both sides of the center of gravity X, rigidity of the circuit component 40 with respect to deformation at a time of vibration can be improved.

As a result of the above, it is possible to prevent the damage to the connection terminal 41 and the fixing portions 431 and 441 even under a severe vibration environment.

In the present embodiment, a third fixing portion can be provided as well as the fixing portions 431 and 441.

When the number of the fixing portions is increased or rigidities of the fixing portions are improved, a support strength is increased and the vibration resistance is also improved.

Here, in the present embodiment, by disposing the fixing portions 431 and 441 on both sides of the center of gravity X, it is possible to secure the sufficient vibration resistance of the circuit component 40 even without increasing the number of the fixing portions or improving the rigidities of the fixing portions.

As long as the fixing portions 431 and 441 are positioned on both sides of the center of gravity X, the fixing arms 43 and 44 can be configured as desired. When a distance from the center of gravity X to the fixing portion 431 and a distance from the center of gravity X to the fixing portion 441 are shorter rather than longer, it is more likely to be able to prevent the deformation occurring during the vibrations. Thus, it is preferable that lengths of the fixing arms 43 and 44 be short.

The circuit assembly 20 can also be fixed on a cylindrically-shaped side surface of the housing 13.

### Second Embodiment

Next, a second embodiment of the present invention will be described.

In the same manner as the first embodiment, the second embodiment also relates to positions of the fixing portions of the circuit component 40 provided in the circuit assembly 20 that functions as the circuit for driving and controlling the motor 11 of the electric compressor 10.

Points that are different from the configuration described in the first embodiment will be mainly described below. The same reference signs will be assigned to the same configuration as the configuration described in the first embodiment.

In the second embodiment, in order to more fully bear the exciting force on the circuit component 40, the fixing portions 431 and 441 and the connection terminal 41 are disposed around the center of gravity X of the circuit component 40 in a well-balanced manner.

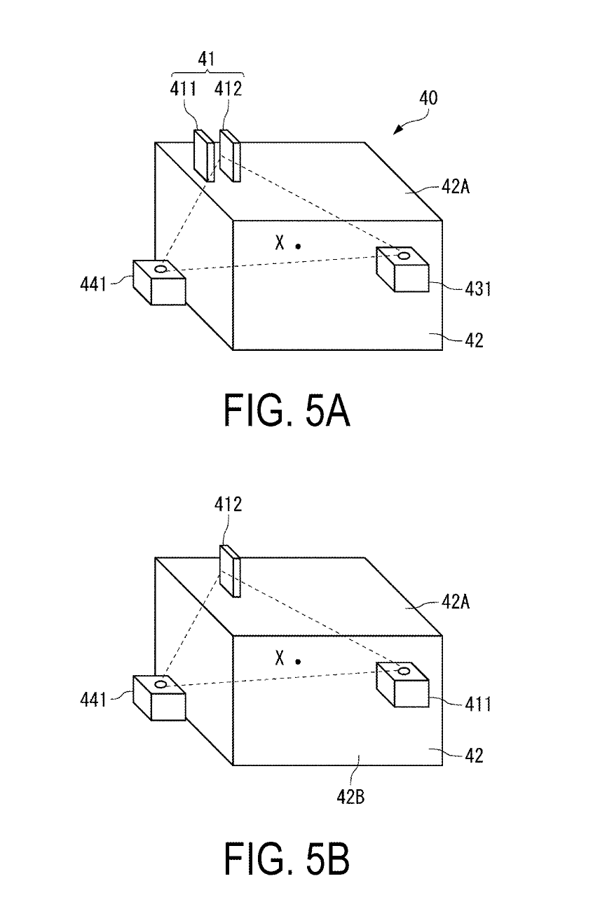

In order to do so, in the present embodiment, as illustrated in FIG. 5A, a centroid of a shape (a triangle indicated by a broken line) that is obtained by linking the fixing portion 431, the fixing portion 441, and the connection terminal 41 is caused to match the center of gravity X of the circuit component 40.

Note that the positive connection terminal 411 and the negative connection terminal 412, which are disposed in proximity to each other, are regarded as being one of vertices of the triangle.

In the present embodiment, in order to cause the connection terminal 41 to reliably support the circuit component 40, it is preferable to improve the rigidity of the circuit terminal 41 to be equivalent to that of the fixing portions 431 and 441.

Because of the fixing portion 431, the fixing portion 441, and the connection terminal 41, which are disposed around the center of gravity X, the exciting force acting upon the center of gravity X of the circuit component 40 is received in a well-balanced manner.

The exciting force acting upon the center of gravity X in the direction orthogonal to the circuit board 21, in the in-plane direction of the circuit board 21, and in any other direction is sufficiently and evenly borne in a non-biased manner by the fixing portion 431, the fixing portion 441, and the connection terminal 41, each of which forms a vertex of the shape that has the center of gravity X as the centroid.

According to the present embodiment, the rigidity to prevent deformation at a time of vibration is further improved. Thus, it is possible to more reliably prevent the damage to the connection terminal 41 and the fixing portions 431 and 441.

### Modified Example of Second Embodiment

FIG. 5B illustrates a modified example of the second embodiment.

The negative connection terminal 412 is positioned on the facing surface 42A of the component body 42. The negative connection terminal 412 is directly fixed to the circuit board 21 by being inserted into the recess of the terminal portion provided in the circuit board 21.

Meanwhile, the positive connection terminal 411 is positioned on one side surface 42B of the component body 42. The positive connection terminal 411 is connected to the circuit board 21 via a connector that is not illustrated in the drawings.

In the present example, the positive connection terminal 411 is used as a fixing portion for fixing the circuit component 40 to the circuit casing 30. The positive connection terminal 411 used as the fixing portion can be fixed by a bolt to a boss provided in the circuit casing 30.

Because the positive connection terminal 411 is used as the fixing portion, one of the fixing portions 431 and 441 can be omitted. Here, the fixing portion 431 is omitted, and the fixing portion 441 is kept.

A centroid of a triangle obtained by linking the positive connection terminal 411, the negative connection terminal 412, and the fixing portion 441 matches the center of gravity X of the circuit component 40.

Therefore, according to the present example also, it is possible to obtain the same effects as those of the second embodiment.

In the second embodiment and the modified example of the second embodiment, the centroid of the shape formed by the connection terminal 41 (the positive connection terminal 411 and the negative connection terminal 412) and the fixing portions 431 and 441 need not necessarily perfectly match the center of gravity X of the circuit component 40. Even when the centroid of the shape is shifted with respect to the center of gravity X, the same effects can be obtained. In the present invention, as long as the center of gravity X of the circuit component 40 is positioned inside the shape formed by the connection terminal 41 and the fixing portions 431 and 441, even when the centroid is shifted, an object of the present invention can be achieved.

In the second embodiment and the modified example of the second embodiment, when the number of the fixing portions is increased or the rigidities of the fixing portions are improved, the support strength is increased and the vibration resistance is also improved.

However, according to the second embodiment and the modified example of the second embodiment, by matching the centroid of the shape with the position of the center of gravity X so that the center of gravity of the circuit component 40 is positioned inside the shape formed by the fixing portions and the connection terminal, it is possible to secure the sufficient vibration resistance of the circuit component 40 without increasing the number of the fixing portions or improving the rigidities of the fixing portions.

Besides the above-described embodiments, as long as there is no departure from the spirit and scope of the present invention, configurations explained in the above-described embodiments can be selected as desired, or can be changed to other configurations as necessary.

In the present invention, there is no restriction on a type of the compression mechanism provided in the electric compressor or a type of the motor.

The circuit components provided in the circuit assembly of the present invention can be applied not only to a capacitor, but also to a coil, other electrical elements, and electronic elements.

### REFERENCE SIGNS LIST

10 Electric compressor
11 Motor
12 Compressor
13 Housing
20 Circuit assembly
21 Circuit board
22 to 25 Circuit component
27 Bolt
28 Fixing portion
29 Bolt
30 Circuit casing
31 Partition wall
32 Peripheral wall
33 Boss
40 Circuit component
41 Connection terminal
42 Component body
42A Facing surface
42B One side surface
43 Fixing arm
44 Fixing arm
111 Stator
112 Rotor
113 Shaft
121 Fixed scroll
122 Orbiting scroll
130 Opening
221 Glass terminal
331 Boss
332 Boss
411 Positive connection terminal
412 Negative connection terminal
431 Fixing portion (First fixing portion)
431A Bolt hole
441 Fixing portion (Second fixing portion)
441A Bolt hole
L Straight line
X Center of gravity

1-5. (canceled)

6. A circuit assembly, comprising:
a circuit board;
a circuit component connected to the circuit board; and
a casing housing both the circuit board and the circuit component;
the circuit component including
a component body disposed facing the circuit board inside the casing,
a connection terminal directly fixed to the circuit board, and
a first fixing portion and a second fixing portion that are provided on the component body and fixed to the casing around the component body,
the first fixing portion being positioned on a side of the circuit board with respect to a center of gravity of the circuit component in a direction orthogonal to the circuit board, and
the second fixing portion being positioned on a side away from the circuit board with respect to the center of gravity in the direction orthogonal to the circuit board.

7. The circuit assembly according to claim 6, wherein the first fixing portion is positioned on one side of a straight line drawn in an in-plane direction of the circuit board so as to pass through the center of gravity, and
the second fixing portion is positioned on the other side of the straight line.

8. A circuit assembly, comprising:
a circuit board;
a circuit component connected to the circuit board; and
a casing housing both the circuit board and the circuit component,
the circuit component including
a component body disposed facing the circuit board inside the casing,
a connection terminal directly fixed to the circuit board, and
at least two fixing portions provided in the component body and fixed to the casing around the component body, and
a center of gravity of the circuit component being positioned inside a shape obtained by linking the connection terminal and the fixing portions.

9. The circuit assembly according to claim 8, wherein one of a positive connection terminal and a negative connection terminal forming the connection terminal is directly fixed to the circuit board, and
the other is used as one of the fixing portions.

10. A vehicular electric compressor, comprising:
the circuit assembly described in claim 6;
a motor driven by a circuit operation of the circuit assembly; and
a compression mechanism compressing a fluid using a driving force transmitted from the motor;
the vehicular electric compressor being mounted in a vehicle.
